(19) United States
(12) Patent Application Publication
(10) Pub. No.: US 2018/0033442 A1
(43) Pub. Date: Feb. 1, 2018

(54) AUDIO CODEC SYSTEM AND AUDIO CODEC METHOD

(71) Applicant: MediaTek Inc., Hsin-Chu (TW)

(72) Inventors: Chi-Peng CHANG, New Taipei City (TW); Sung-Han WEN, Taipei City (TW); Chieh-Tsen LIN, Hsinchu City (TW)

(21) Appl. No.: 15/221,937

(22) Filed: Jul. 28, 2016

(51) Int. Cl. G10L 19/04; G10L 25/09; H03G 3/20; G10L 25/21

(52) U.S. Cl. CPC G10L 19/04; G10L 25/21; G10L 25/09; H03G 3/20

(57) ABSTRACT

An audio codec system which uses a memory to buffer frames of audio while signal power levels of the frames of audio buffered in the memory are detected to generate a signal power look-forward value and zero-crossing points of the frames of audio buffered in the memory are detected to obtain available calibration points for gain control due to a change of the signal power look-forward value. The gain control is divided to be performed at the available calibration points.

### BACKGROUND OF THE INVENTION

### Field of the Invention

The present invention relates to an audio codec system and method.

### Description of the Related Art

Audio codec technology is commonly used in consumer electronics. Considering the user's listening experience, accurate and real-time gain control of an audio codec chip is called for to eliminate peak noise. Enhanced signal-to-noise ratio and dynamic range are needed.

### BRIEF SUMMARY OF THE INVENTION

An audio codec system in accordance with an exemplary embodiment of the disclosure includes a memory capable of buffering frames of audio, a signal power detector capable of detecting signal power levels of the frames of audio buffered in the memory to generate a signal power look-forward value, a zero-crossing detector capable of detecting zero-crossing points of the frames of audio buffered in the memory to obtain available calibration points for gain control due to a change of the signal power look-forward value, and a dynamic range enhancement gain controller, capable of dividing the gain control to be performed at the available calibration points.

An audio codec method in accordance with an exemplary embodiment of the disclosure includes the following steps: providing a memory capable of buffering frames of audio; detecting signal power levels of the frames of audio buffered in the memory to generate a signal power look-forward value; detecting zero-crossing points of the frames of audio buffered in the memory to obtain available calibration points for gain control due to a change of the signal power look-forward value; and dividing the gain control to be performed at the available calibration points.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 depicts an audio codec system 100 in accordance with an exemplary embodiment of the disclosure;

FIG. 2 shows the codec performance in accordance with an exemplary embodiment of the disclosure;

FIG. 3 shows the sequence SPL(n) and the sequence Pre_Zce(n) in accordance with an exemplary embodiment of the disclosure, wherein the memory 102 continuously buffers 6 frames of audio;

FIG. 4 is a flowchart depicting the operations of the DRE gain controller 108; and

FIG. 5 shows how the divided digital gain control and the divided analog gain control are performed on the audio codec chip 110 with respect to the example of FIG. 3 and the flowchart of FIG. 4.

### DETAILED DESCRIPTION OF THE INVENTION

The following description shows exemplary embodiments of the invention. This description is made for the purpose of illustrating the general principles of the invention and should not be taken in a limiting sense. The scope of the invention is best determined by reference to the appended claims.

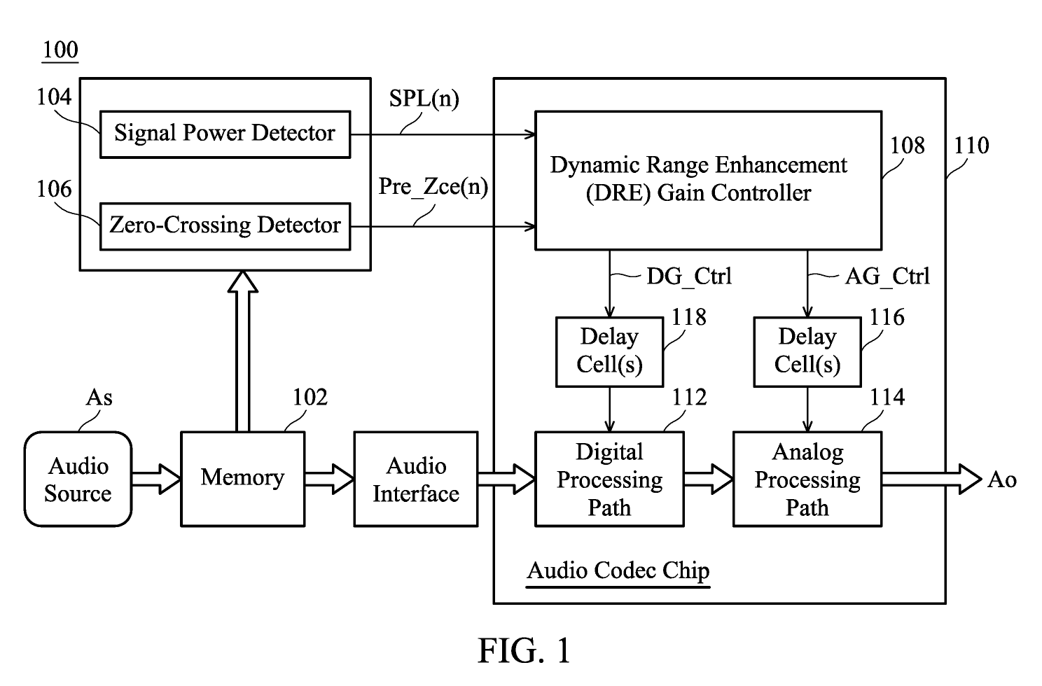

FIG. 1 depicts an audio codec system 100 in accordance with an exemplary embodiment of the disclosure, which may convert an audio source As into an audio output Ao. Frames of audio provided from the audio source As may be buffered (e.g. continuously buffered) in a memory 102 to be retrieved by a signal power detector 104 and a zero-crossing detector 106. At each time point, the signal power detector 104 may detect signal power levels of the frames of audio buffered in the memory 102 and may thereby generate a corresponding signal power look-forward value and, for gain control due to a change of the generated signal power look-forward value, the zero-crossing detector 106 may detect zero-crossing points of the frames of audio buffered in the memory 102 and may thereby obtain corresponding available calibration points. In FIG. 1, a variable n shows the frame index. A sequence SPL(n) is shown to represent the signal power look-forward values generated at different time points, and the amounts of available calibration points obtained at different time points can be found in a sequence Pre_Zce(n). A dynamic range enhancement (DRE) gain controller 108 may be coupled to the signal power detector 104 and the zero-crossing detector 106. According to the sequence SPL(n) and the sequence Pre_Zce(n), the DRE gain controller 118 may know the number of available calibration points that can be used in contributing to the gain control of each change of the signal power look-forward value. Accordingly, the DRE gain controller 118 may divide the gain control for each change of the signal power look-forward value to be performed at the corresponding available calibration points. In this manner, gain control can be achieved smoothly with gapless codec performance.

For an audio codec chip 110 that may retrieve the memory 102 and provide a digital processing path 112 and an analog processing path 114 for each frame of audio retrieved from the memory 102, the DRE gain controller 108 may generate a digital gain control signal DG_Ctrl to control a digital gain of the digital processing path 112 and an analog gain control signal AG_Ctrl to control an analog gain of the analog processing path 114. As shown, each frame of audio retrieved from the memory 102 may be sent to the digital processing path 112 and then sent to the analog processing path 114. A digital gain adjustment that the dynamic range enhancement gain controller 108 may perform on the digital gain may be compensated by an analog gain adjustment that the dynamic range enhancement gain controller 108 may perform on the analog gain. To synchronize the analog gain adjustment performed on the analog gain of the analog processing path 114 with the digital gain adjustment performed on the digital gain of the digital processing path 112, delay cell(s) may be provided to delay the analog gain control signal AG_Ctrl (referring to the delay cell(s) 116) or further provided to delay the digital gain control signal DG_Ctrl (referring to the delay cell(s) 118).

Furthermore, in this exemplary embodiment, the memory 102 is a system memory of the audio codec system 100 and is external to the audio codec chip 110. Thus, there is no need to equip a large-sized memory within the audio codec chip 110, and the production cost of the audio codec chip 110 can be considerably reduced.

The DRE gain controller 108 may be a hardware implementation within the audio codec chip 110 and the signal power detector 104 and the zero-crossing detector 106 may be implemented by system software to be executed by a microprocessor of the audio codec system 100. In other exemplary embodiments, the functions of the DRE gain controller 108 may be also provided by the system software of the audio codec system 100. It is not intended to limit the DRE gain controller, the signal power detector and the zero-crossing detector of the disclosure to hardware or software implementation.

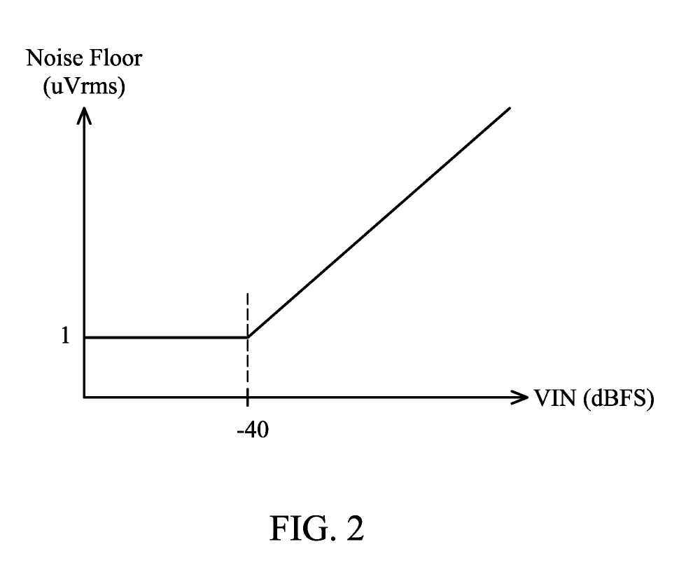

FIG. 2 shows the codec performance in accordance with an exemplary embodiment of the disclosure. The increasing power VIN of the audio source As does not severely increase the noise floor. Instead, a gapless codec performance is shown.

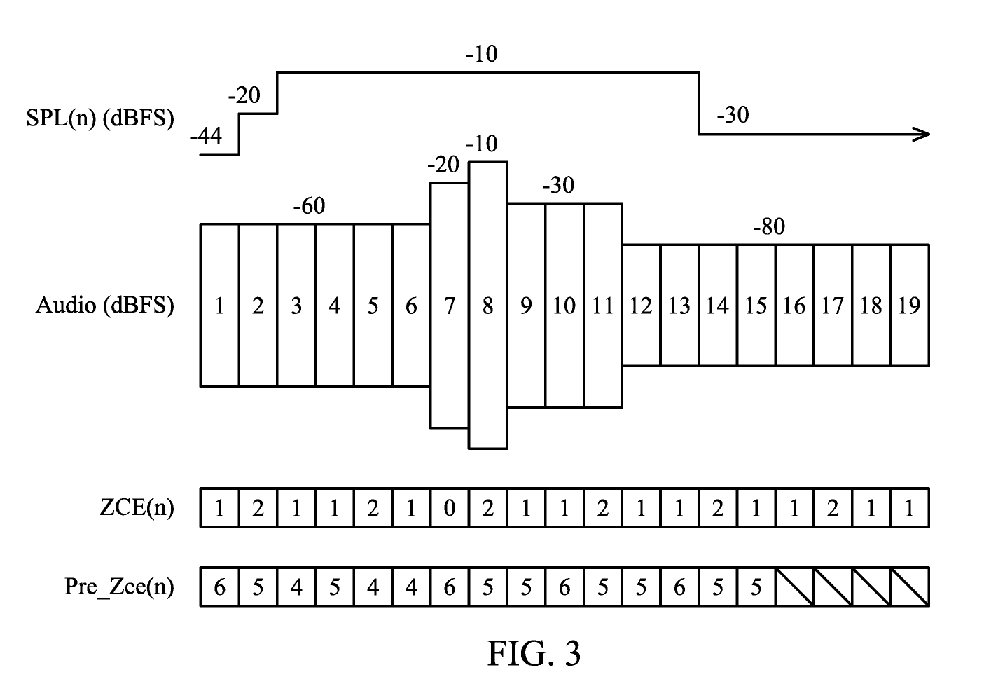

FIG. 3 shows the sequence SPL(n) and the sequence Pre_Zce(n) in accordance with an exemplary embodiment of the disclosure, wherein the memory 102 may continuously buffer 6 frames of audio.

When the 1^{st} to the 6^{th} frames of audio are buffered in the memory 102, an initial signal power look-forward value SPL(1) may be generated by the signal power detector 104 and the zero-crossing detector 106 may detect the zero-crossing points of the 1^{st} to the 6^{th} frames of audio to get the number of zero-crossing points ZCE(1) to ZCE(6) in the different frames of audio and may accumulate the zero-crossing points of the 2^{nd} to the 5^{th} frames of audio to get a value Pre_Zce(1) (=ZCE(2)+ZCE(3)+ZCE(4)+ZCE(5)). As shown, the 1^{st} to the 6^{th} frames of audio may be maintained at low power −60 dBFS. Because of the control limitation of the audio codec chip 110, the initial signal power look-forward value SPL(1) may be −44 dBFS.

When the 2^{nd} to the 7^{th} frames of audio are buffered in the memory 102 (wherein the 2^{nd} frame is the 1^{st} frame buffered in the memory 102 and the 7^{th} frame is the M^{th} frame buffered in the memory 102, M=6 here), a signal power look-forward value SPL(2) may be generated by the signal power detector 104 and the zero-crossing detector 106 may further detect the zero-crossing points of the 7^{th} frame of audio to get the number of zero-crossing points ZCE(7) in the 7^{th} frame of audio and may accumulate the zero-crossing points of the 3^{rd} to the 6^{th} frames of audio to get a value Pre_Zce(2) (=ZCE(3)+ZCE(4)+ZCE(5)+ZCE(6)). As shown, the power of the 7^{th} frame may increase to −20 dBFS and, accordingly, the signal power detector 104 may use an increment of the signal power look-forward value (from −44 dBFS to −20 dBFS) to reflect the increase of the signal power levels of the 2^{nd} to the 7^{th} frames of audio. Note that the signal power look-forward value SPL(2) may be set to −20 dBFS, the same as the greater signal power level (−20 dBFS of the 7^{th} frame of audio) detected by the signal power detector 104 in comparison with the current frame of audio (i.e., the 2^{nd} frame of audio which is at −60 dBFS). The zero-crossing points of the 3^{rd} to the 6^{th} frames of audio (wherein the 3^{rd} frame is the 2^{nd} frame buffered in the memory 102 and the 6^{th} frame is the (M−1)^{th} frame buffered in the memory 102, M=6 here) may be regarded as the available calibration points for the gain control due to the change of the signal power look-forward value (from SPL(1)=−44 dBFS to SPL(2)=−20 dBFS). The value Pre_Zce(2) (=5) may show the number of available calibration points. Five available calibration points can be used in contributing to the gain control due to the change of the signal power look-forward value (from SPL(1)=−44 dBFS to SPL(2)=−20 dBFS). In another exemplary embodiment, when the play of the 2^{nd} frame of audio (wherein the 2^{nd} frame is the 1^{st} frame buffered in the memory) has not been finished, the corresponding zero-crossing points in the remaining 2^{nd} frame of audio may be also regarded as the available calibration points.

When the 3^{rd} to the 8^{th} frames of audio are buffered in the memory 102 (wherein the 3^{rd} frame is the 1^{st} frame buffered in the memory 102 and the 8^{th} frame is the M^{th} frame buffered in the memory 102, M=6 here), a signal power look-forward value SPL(3) may be generated by the signal power detector 104 and the zero-crossing detector 106 may further detect the zero-crossing points of the 8^{th} frame of audio to get the number of zero-crossing points ZCE(8) in the 8^{th} frame of audio and may accumulate the zero-crossing points of the 4^{th} to the 7^{th} frames of audio to get a value Pre_Zce(3) (=ZCE(4)+ZCE(5)+ZCE(6)+ZCE(7)). As shown, the power of the 8^{th} frame may increase to −10 dBFS and thereby the signal power detector 104 may use an increment of the signal power look-forward value (from −20 dBFS to −10 dBFS) to reflect the increase of the signal power levels of the 3^{rd} to the 8^{th} frames of audio. Note that the signal power look-forward value SPL(3) may be set to −10 dBFS, the same as the greater signal power level (−10 dBFS of the 8^{th} frame of audio) detected by the signal power detector 104 in comparison with the current frame of audio (i.e., the 3^{rd} frame of audio which is at −60 dBFS). The zero-crossing points of the 4^{th} to the 7^{th} frames of audio (wherein the 4^{th} frame is the 2^{nd} frame buffered in the memory 102 and the 7^{th} frame is the (M−1)^{th} frame buffered in the memory 102, M=6 here) may be regarded as the available calibration points for the gain control due to the change of the signal power look-forward value (from SPL(2)=−20 dBFS to SPL(3)=−10 dBFS). The value Pre_Zce(3) (=4) may show the number of available calibration points. Four available calibration points can be used in contributing to the gain control due to the change of the signal power look-forward value (from SPL(2)=−20 dBFS to SPL(3)=−10 dBFS). In another exemplary embodiment, when the play of the 3^{rd} frame of audio (wherein the 3^{rd} frame is the 1^{st} frame buffered in the memory) has not been finished, the corresponding zero-crossing points in the remaining 3^{rd} frame of audio may be also regarded as the available calibration points.

As for a decrease of the signal power levels of the frames of audio, the signal power detector 104 may delay a decrement of the signal power look-forward value until foreseeable frames of audio do not need the signal power look-forward value before the decrement. As shown, although the decreasing power from −10 dBFS of the 8^{th} frame of audio to −30 dBFS of the 9^{th} frame of audio may be obtained when the 4^{th} to the 9^{th} frames of audio are buffered in the memory 102, the decrement of the signal power look-forward value may be delayed to the time point that the memory 102 is buffering the 14^{th} to the 19^{th} frames of audio. As shown, the foreseeable frames of audio (the 14^{th} to the 19^{th} frames of audio) may not need the signal power look-forward value before the decrement. The value Pre_Zce(14) (=5) may show the number of available calibration points. Five available calibration points can be used in contributing to the gain control due to the change of the signal power look-forward value (from SPL(13)=−10 dBFS to SPL(14)=−30 dBFS).

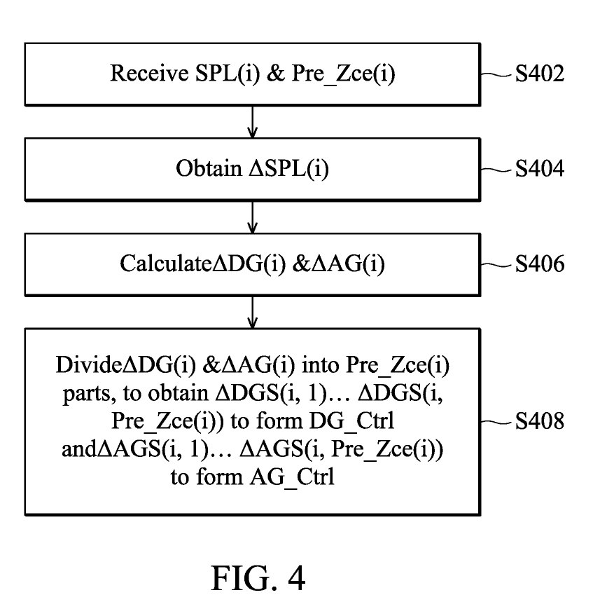

FIG. 4 is a flowchart depicting the operations of the DRE gain controller 108. The i^{th} frame of audio is the current frame of audio to be processed by the audio codec chip 110. In step S402, the DRE gain controller 108 may receive the signal power look-forward value SPL(i) from the signal power detector 104 and a number Pre_Zce(i) from the zero-crossing detector 106. In step S404, a change ΔSPL(i) of the signal power look-forward value may be obtained by comparing the current signal power look-forward value SPL(i) with the previous signal power look-forward value SPL(i−1). In step S406, a digital gain control ΔDG(i) due to the change ΔSPL(i) of the signal power look-forward value and an analog gain control ΔAG(i) due to the change ΔSPL(i) of the signal power look-forward value may be calculated. In step S408, based on the number of available calibration points Pre_Zce(i), the digital gain control ΔDG(i) and the analog gain control ΔAG(i) may be divided into Pre_Zce(i) parts. The divided digital gain control ΔDGS(i, 1) . . . ΔDGS(i, Pre_Zce(i)) and the divided analog gain control ΔAGS(i, 1) . . . ΔAGS(i, Pre_Zce(i)) may be obtained to form the digital gain control signal DG_Ctrl and the analog gain control signal AG_Ctrl.

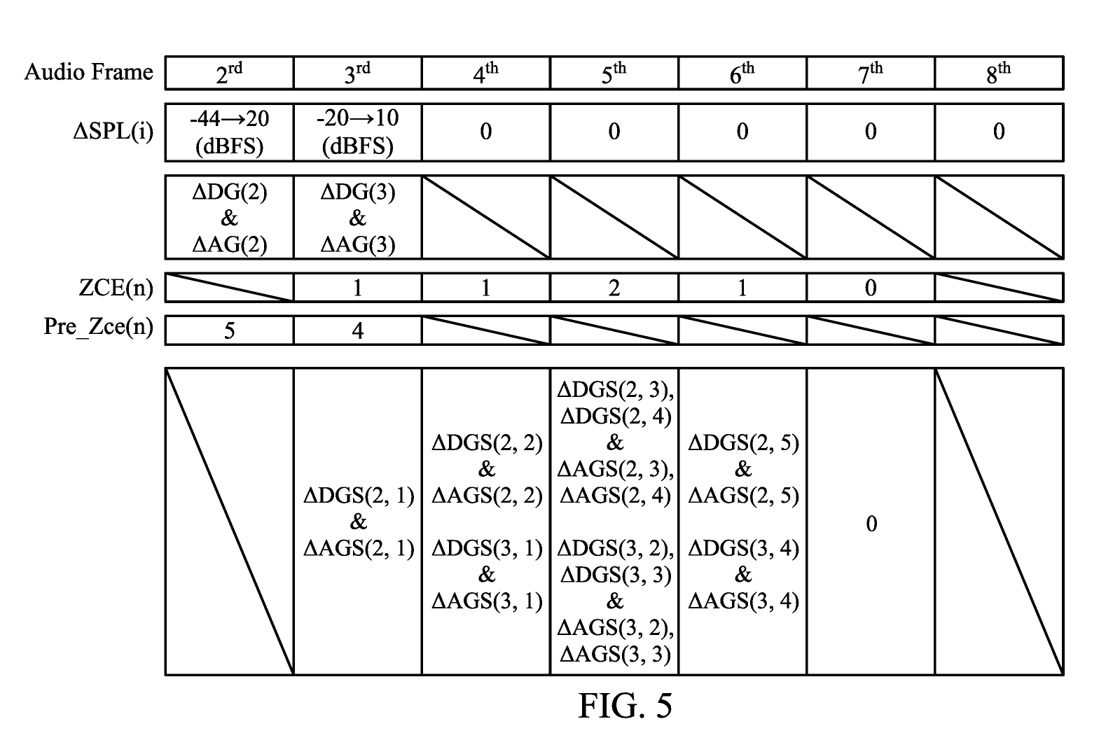

FIG. 5 shows how the divided digital gain control and the divided analog gain control are performed on the audio codec chip 110 with respect to the example of FIG. 3 and the flowchart of FIG. 4.

Supposing the current frame of audio to be processed by the audio codec chip 110 is the 2^{nd} frame of audio, the change ΔSPL(2) of the signal power look-forward value may be obtained (from SPL(1)=−44 dBFS to SPL(2)=−20 dBFS) and, accordingly, the digital gain control ΔDG(2) and the analog gain control ΔAG(2) may be calculated. Because the available calibration points for the digital gain control ΔDG(2) and the analog gain control ΔAG(2) may be the zero-crossing points of the 3^{rd} to the 6^{th} frames of audio, the divided digital gain control ΔDGS(2, 1) may contribute to the digital gain control of 3^{rd} frame of audio and the divided analog gain control ΔAGS(2, 1) may contribute to the analog gain control of 3^{rd} frame of audio, the divided digital gain control ΔDGS(2, 2) may contribute to the digital gain control of 4^{th} frame of audio and the divided analog gain control ΔAGS(2, 2) may contribute to the analog gain control of 4^{th} frame of audio, the divided digital gain control ΔDGS(2, 3) and ΔDGS(2, 4) may contribute to the digital gain control of 5^{th} frame of audio and the divided analog gain control ΔAGS(2, 3) and ΔAGS(2, 4) may contribute to the analog gain control of 5^{th} frame of audio, and the divided digital gain control ΔDGS(2, 5) may contribute to the digital gain control of 6^{th} frame of audio and the divided analog gain control ΔAGS(2, 5) may contribute to the analog gain control of 6^{th} frame of audio.

Supposing the current frame of audio to be processed by the audio codec chip 110 is the 3^{rd} frame of audio, the change ΔSPL(3) of the signal power look-forward value may be obtained (from SPL(2)=−20 dBFS to SPL(3)=−10 dBFS) and, accordingly, the digital gain control ΔDG(3) and the analog gain control ΔAG(3) may be calculated. Because the available calibration points for the digital gain control ΔDG(3) and the analog gain control Δ AG(3) may be the zero-crossing points of the 4^{th} to the 7^{th} frames of audio, the divided digital gain control ΔDGS(3, 1) may contribute to the digital gain control of 4^{th} frame of audio and the divided analog gain control ΔAGS(3, 1) may contribute to the analog gain control of 4^{th} frame of audio, the divided digital gain control ΔDGS(3, 2) and ΔDGS(3, 3) may contribute to the digital gain control of 5^{th} frame of audio and the divided analog gain control ΔAGS(3, 2) and ΔAGS(3, 3) may contribute to the analog gain control of 5^{th} frame of audio, the divided digital gain control ΔDGS(3, 4) may contribute to the digital gain control of 6^{th} frame of audio and the divided analog gain control ΔAGS(3, 4) may contribute to the analog gain control of 6^{th} frame of audio, and no digital or analog gain control may be performed on the 7^{th} frame of audio because no zero-crossing point is detected in the 7^{th} frame of audio. The digital gain control signal DG_Ctrl and the analog gain control signal AG_Ctrl that the DRE gain controller 108 may output to the digital processing path 112 and the analog processing path 114 of the audio codec chip 110 can be obtained from the bottom line of information shown in FIG. 5.

In some exemplary embodiments, audio codec methods are introduced. An audio codec method in accordance with an exemplary embodiment of the disclosure may provide the following steps: providing a memory capable of buffering frames of audio; detecting signal power levels of the frames of audio buffered in the memory to generate a signal power look-forward value; detecting zero-crossing points of the frames of audio buffered in the memory to obtain available calibration points for gain control due to a change of the signal power look-forward value; and dividing the gain control to be performed at the available calibration points.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An audio codec system, comprising:
a memory, capable of buffering frames of audio;
a signal power detector, capable of detecting signal power levels of the frames of audio buffered in the memory to generate a signal power look-forward value;
a zero-crossing detector, capable of detecting zero-crossing points of the frames of audio buffered in the memory to obtain available calibration points for gain control due to a change of the signal power look-forward value; and
a dynamic range enhancement gain controller, capable of dividing the gain control to be performed at the available calibration points.

2. The audio codec system as claimed in claim 1, wherein:
the signal power detector uses an increment of the signal power look-forward value to reflect an increase of the signal power levels of the frames of audio buffered in the memory.

3. The audio codec system as claimed in claim 1, wherein:
when detecting a greater signal power level in comparison with a current frame of audio, the signal power detector regards the greater signal power level as the signal power look-forward value.

4. The audio codec system as claimed in claim 3, wherein:
when the greater signal power level is obtained from the M^{th} frame of audio buffered in the memory, the zero-crossing detector regards the zero-crossing points of the 2^{nd} to (M−1)^{th} frames of audio buffered in the memory as the available calibration points; and
M is a number.

5. The audio codec system as claimed in claim 1, wherein:
for a decrease of the signal power levels of the frames of audio, the signal power detector delays a decrement of the signal power look-forward value until foreseeable frames of audio do not need the signal power look-forward value before the decrement.

6. The audio codec system as claimed in claim 1, further comprising:
an audio codec chip, capable of retrieving the memory and providing a digital processing path and an analog processing path for each frame of audio retrieved from the memory,
wherein a digital gain of the digital processing path and an analog gain of the analog processing path are adjusted by the dynamic range enhancement gain controller.

7. The audio codec system as claimed in claim 6, wherein:
the memory is a system memory of the audio codec system and is external to the audio codec chip.

8. The audio codec system as claimed in claim 6, further comprising:
at least one first delay cell, capable of delaying an analog gain control signal that the dynamic range enhancement gain controller outputs for the analog gain of the analog processing path of the audio codec chip.

9. The audio codec system as claimed in claim 6, further comprising:
at least one second delay cell, capable of delaying a digital gain control signal that the dynamic range enhancement gain controller outputs for the digital gain of the digital processing path of the audio codec chip.

10. The audio codec system as claimed in claim 6, wherein:
each frame of audio retrieved from the memory is sent to the digital processing path and then sent to the analog processing path; and
a digital gain adjustment that the dynamic range enhancement gain controller performs on the digital gain is compensated by an analog gain adjustment that the dynamic range enhancement gain controller performs on the analog gain.

11. An audio codec method, comprising:
providing a memory capable of buffering frames of audio;
detecting signal power levels of the frames of audio buffered in the memory to generate a signal power look-forward value;
detecting zero-crossing points of the frames of audio buffered in the memory to obtain available calibration points for gain control due to a change of the signal power look-forward value; and
dividing the gain control to be performed at the available calibration points.

12. The audio codec method as claimed in claim 11, further comprising:
using an increment of the signal power look-forward value to reflect an increase of the signal power levels of the frames of audio buffered in the memory.

13. The audio codec method as claimed in claim 11, wherein:
when a greater signal power level in comparison with a current frame of audio is detected from the frames of audio buffered in the memory, the greater signal power level is regarded as the signal power look-forward value.

14. The audio codec method as claimed in claim 13, wherein:
when the greater signal power level is obtained from the M^{th} frame of audio buffered in the memory, the zero-crossing points of the 2^{nd} to (M−1)^{th} frames of audio buffered in the memory are regarded as the available calibration points; and
M is a number.

15. The audio codec method as claimed in claim 11, wherein:
for a decrease of the signal power levels of the frames of audio, a decrement of the signal power look-forward value is delayed until foreseeable frames of audio do not need the signal power look-forward value before the decrement.

16. The audio codec method as claimed in claim 11, further comprising:
using an audio codec chip to retrieve the memory and provide a digital processing path and an analog processing path for each frame of audio retrieved from the memory,
wherein a digital gain of the digital processing path and an analog gain of the analog processing path are adjusted by the divided gain control.

17. The audio codec method as claimed in claim 16, wherein:
the memory is a system memory of an audio codec system and is external to the audio codec chip; and
the audio codec chip is provided within the audio codec system.

18. The audio codec method as claimed in claim 16, further comprising:
synchronizing an analog gain adjustment performed on the analog gain with a digital gain adjustment performed on the digital gain.

19. The audio codec method as claimed in claim 16, wherein:
each frame of audio retrieved from the memory is sent to the digital processing path and then sent to the analog processing path; and
a digital gain adjustment performed on the digital gain is compensated by an analog gain adjustment performed on the analog gain.
